(19) United States
(12) Patent Application Publication
(10) Pub. No.: US 2018/0100877 A1
(43) Pub. Date: Apr. 12, 2018

(54) CURRENT DETECTION DEVICE

(71) Applicant: KOA CORPORATION, Ina-shi, Nagano (JP)

(72) Inventors: Keishi Nakamura, Ina-shi (JP); Hitoshi Amemiya, Ina-shi (JP); Koichi Minowa, Ina-shi (JP)

(73) Assignee: KOA CORPORATION, Ina-shi, Nagano (JP)

(21) Appl. No.: 15/568,882

(22) PCT Filed: Apr. 21, 2016
(86) PCT No.: PCT/JP2016/062599

§ 371 Date: Oct. 24, 2017

(30) Foreign Application Priority Data
Apr. 28, 2015 (JP) 2015-091427

(51) Int. Cl. G01R 1/20; G01R 31/36; H01M 10/42; H01M 10/48; H01R 11/28; G01R 19/165

(52) U.S. Cl. CPC G01R 1/203; G01R 31/3696; G01R 19/16542; H01M 10/48; H01R 11/287; H01M 10/425

(57) ABSTRACT

A current detection device formed as a shunt resistor is configured such that, when using the device for connecting to a bus bar, which configures a current path, by rotational fixing with fixing members, rotational force is not applied to joint interface between a resistor body and wiring members of the shunt resistor. The device includes a first wiring member and a second wiring member those consisting of a conductive metal material, and a resistor body consisting of a metal material having a lower temperature coefficient of resistance than those wiring members and is joined onto the first wiring member and the second wiring member, wherein the first wiring member is provided with a through hole, into which a fixing member for rotational fixing is inserted, and a positioning portion, which serves to prevent rotation of the first wiring member caused by rotational fixing with fixing members.

### TECHNICAL FIELD

The present invention relates to a current detection device for measuring a current flowing through a bus bar etc., especially relating to a shunt type current detection device, which is able to measure a current with high accuracy as a shunt resistor, while using the bus bar as current wirings of the shunt resistor.

### BACKGROUND ART

The current is conventionally detected by using the shunt resistor, which measures a voltage caused by the current flowing through the shunt resistor in various kinds of current detections. The detections include, detection of electrical charge and discharge current in a battery, detection of motor current that drives an electric vehicle or a hybrid-power car etc., detection of current in electric equipment such as air conditioner, and detection of current in power generating machines including solar battery etc.

In case of a bus bar used as a current path from power supply such as batteries to various electrical equipment, the shunt resistor for current detection must be connected with the bus bar. In such a case, the bus bar and the shunt resistor are conventionally connected by screwing stop or soldering for fixing a terminal or an electrode of the shunt resistor and a terminal of the bus bar (see Japanese laid open patent publication 2011-003694).

However, according to such connection between the bus bar and the shunt resistor, because of increase of connection, heat generation occurs by contact resistance of the connection between them, and problem of securing connection reliability occurs. Then, a current detection device that can be used for detecting a large current with high reliability is required. Japanese laid open patent publication 2008-039571 discloses a bus bar type shunt resistor, which includes a first long wiring member, a second wiring member, and a resistor body welded and fixed between the first and the second wiring members (see FIG. 6 etc.).

### SUMMARY OF INVENTION

### Technical Problem

However, when another bus bar, which is a current path, is connected to a bus bar configured as a shunt resistor by rotational fixing (screwing stop) with fixing members (bolt and nut etc.), a rotational force by rotational fixing with the fixing members affects the shunt resistor. Then, joint interfaces between the wiring members and the resistor body become affected, and a problem that accuracy of current detection becomes deteriorated occurs.

The invention has been made basing on above-mentioned circumstances. Thus, an object of the invention is to provide a shunt type current detection device, which is capable of avoiding a rotational force from being applied onto the joint interfaces with resistor body, when another bus bar of current path is rotationally fixed to the bus bar configured as the shunt resistor with fixing members.

### Solution to Problem

The current detection device according to the invention includes a first wiring member and a second wiring member those consisting of a conductive metal material; a resistor body consisting of a metal material having a lower temperature coefficient of resistance than those wiring members, and the resistor body joined onto the first wiring member and the second wiring member; a through hole formed in the first wiring member for inserting a fixing member for rotational fixing; and a positioning portion for preventing rotation of the first wiring member caused by rotational fixing with fixing members.

Also, according to the current detection device, a through hole in a third wiring member consisting of conductive metal material for configuring a current path is positioned to a through hole in the first wiring member; the first wiring member and the third wiring member are overlapped with each other at a portion of their surfaces; and the first wiring member and the third wiring member are positioned by the positioning portion, and rotationally fixed by the fixing members.

According to the invention, by rotational fixing with fixing members, even though rotational force is applied to first wiring member, since the device includes the positioning portion, which serves to prevent rotation of the first wiring member caused by rotational fixing with fixing members, rotation of the first wiring member is prevented. Therefore, rotational force is not applied to the joint interfaces between the wiring members and the resistor body, and deterioration of current detection accuracy can be prevented.

### BRIEF DESCRIPTION OF DRAWINGS

FIG. 1 is a perspective view of the shunt type current detection device of first embodiment of the invention.

FIG. 2 is a perspective view of the shunt type current detection device of second embodiment of the invention.

FIG. 3 is a perspective view of the shunt type current detection device of third embodiment of the invention.

FIG. 4 is a perspective view of the shunt type current detection device of fourth embodiment of the invention.

FIG. 5 is a perspective view of the shunt type current detection device of fifth embodiment of the invention.

FIG. 6 is a plan view of the shunt type current detection device of sixth embodiment of the invention.

FIG. 7 is a plan view of the shunt type current detection device of seventh embodiment of the invention.

FIG. 8 is a plan view of the shunt type current detection device of eighth embodiment of the invention.

FIG. 9 is a plan view of the shunt type current detection device of ninth embodiment of the invention.

### DESCRIPTION OF EMBODIMENTS

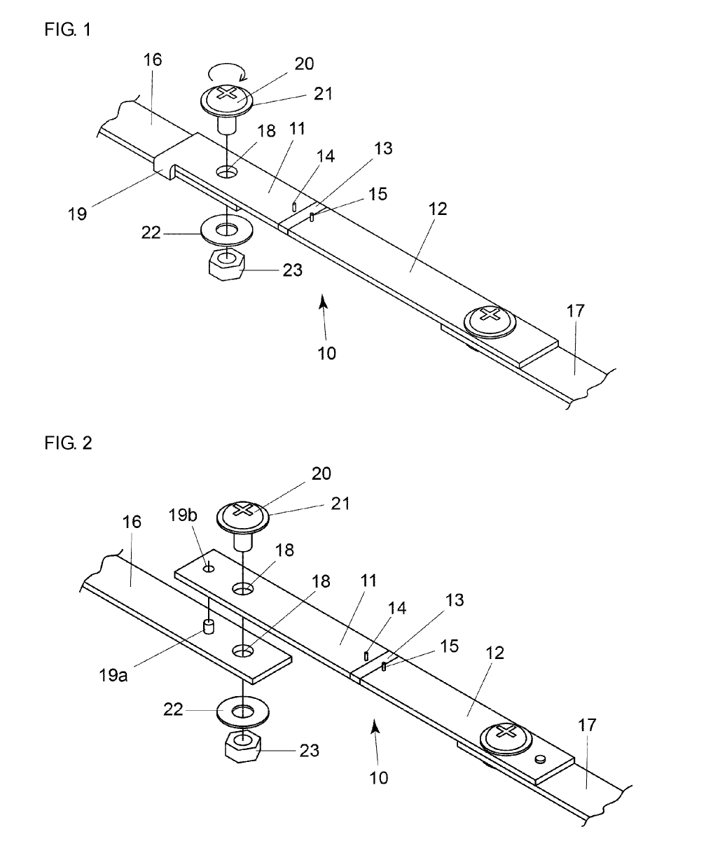

Embodiments of the present invention will be described below with referring to FIG. 1 through FIG. 9. Like or corresponding parts or elements will be denoted and explained by same reference characters throughout views.

FIG. 1 illustrates the shunt type current detection device of first embodiment of the invention. The device 10 includes a first wiring member 11 and a second wiring member 12 those consisting of a conductive metal material such as Cu, Cu system alloy, or Al etc., and a resistor body 13 consisting of a metal material having a lower temperature coefficient of resistance than those wiring members, wherein the resistor body 13 is joined onto the first wiring member 11 and the second wiring member 12 at both ends.

The first wiring member 11 and the second wiring member 12 are bus bars that configures a current path and also terminal members joining onto the resistor body 13 at both ends thereof. The first wiring member 11 and the second wiring member 12 may be same size and same shape or they may be different size and different shape.

The resistor body 13 consists of metal resistor alloy material such as Cu—Mn system alloy, Cu—Ni system alloy, or Ni—Cr system alloy, which has much lower temperature coefficient of resistance than metal material such as Cu etc. Both end faces of resistor body 13 are abutted and welded onto end faces of wiring member 11 and wiring member 12, where joint interfaces between resistor body 13 and terminal members 11,12 are formed. Electron beam welding, laser beam welding, brazing and soldering, etc. can be used for the welding. An end portion of resistor body 13 and an end portion of wiring members 11,12 may be overlapped and pressure-welded to form the joint interface.

Voltage detection terminals 14,15 are provided on wiring members 11,12 at vicinity of both ends of resistor body 13. The current flowing through wiring members 11,12 passes through resistor body 13 and generates a voltage difference between both ends of the resistor body 13. The voltage difference is detected by voltage detection terminals 14,15. Processing means such as a micro-computer for generating a current measuring signal from detected signals by the voltage detection terminals may be mounted on surrounding of the resistor body 13.

Thus, current detection device 10 consisting of first wiring member 11, second wiring member 12, and resistor body 13 is configured as a shunt resistor having a bus bar function. Both or any one of wiring members 11,12, which is connected to resistor body 13, is a long size one, then current detection device 10 is a longer size one than usual shunt resisters. The current detection device 10 is provided with a through hole 18 in first wiring member 11 for inserting a fixing member (bolt) 20 for rotational fixing and a positioning portion 19, which serves to prevent rotation of first wiring member 11 caused by rotational fixing with fixing members (bolt and nut) 20 etc.

The current detection device 10 is connected to a bus bar (third wiring member) 16, which is a current path. First, a through hole 18 in third wiring member 16 consisting of metal material is positioned to the through hole 18 in first wiring member 11. First wiring member 11 and third wiring member 16 are overlapped with each other at a portion of their surfaces, and first wiring member 11 and third wiring member 16 are positioned by positioning portion 19, which is a projected part from first wiring member 11. Here, positioning portion 19 is preferable to be formed at an end of first wiring member opposite to joint interface onto resistor body 13, where through hole 18 is placed between positioning portion 19 and joint interface onto resistor body 13. Then, joint interfaces can be prevented from being affected by rotational fixing with fixing members.

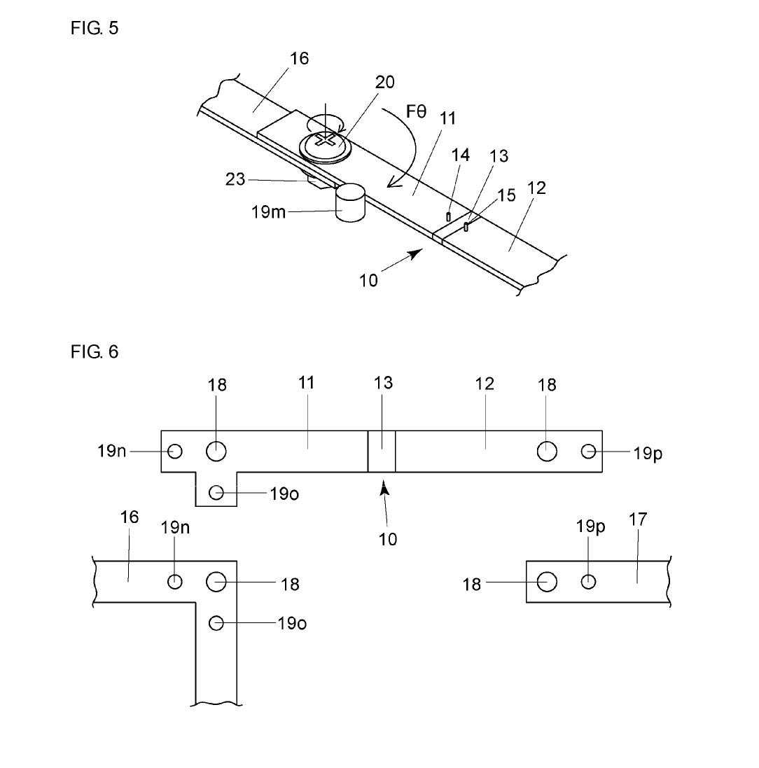

A portion of bus bar (third wiring member) 16 configuring a current path and a portion of current detection device 10 configuring a shunt resistor are fixed with each other by rotational fixing (screwing stop) with fixing members (bolt 20 and nut 23 with washers 21, 22). At this time, rotational force Fθ that centers on bolt 20 caused by rotational fixing with fixing members (bolt 20 etc.) is applied to first wiring member 11 (see FIG. 5). Direction of rotational force Fθ is same with direction of rotation of fixing members (bolt 20 etc.).

However, positioning portion 19 that is a projected part is provided for preventing rotation of first wiring member 11 against rotational force Fθ caused by rotational fixing with bolt 20 etc. That is, positioning portion 19 stops first wiring member 11 from rotating, then first wiring member 11 is positioned to an extension direction of third wiring member 16 (See FIG. 1).

In case that long size wiring members such as wiring members 11,12 are welded to both ends of resistor body 13, rotational force is easily applied to the joint interface between resistor body 13 and wiring member 11. In case that the joint interface is formed by abut-welding, formed joint interface is generally small, and strength of the joint interface is generally weak. According to present invention including the positioning portion, applied rotational force to the joint interface can be decreased.

Because, rotation of first wiring member 11 is stopped by the positioning portion 19, rotational force is not applied to the current detection device 10. Then, joint interface between resistor body 13 and wiring members 11,12 is not affected by the rotational force applied by rotational fixing with fixing members 20 etc. According to conventional structure, there was a problem that rotational force is applied to the joint interface by rotational fixing (screwing stop) of fixing members (bolt 20 etc.). According to the present invention, the problem can be solved and deterioration of current detection accuracy can be prevented.

Positioning portion 19 may be formed in third wiring member 16. That is, the projected part of positioning portion 19 may be formed in third wiring member 16 at a position, where rotation of wiring member 11 that centers at bolt 20 by rotational fixing of bolt 20 etc. can be stopped. Further, the projected part of positioning portion 19 may be formed in second wiring member 12.

FIG. 2 illustrates a current detection device of second embodiment, in which, the positioning portion is formed as a convex portion 19a on third wiring member 16 and a hole 19b in first wiring member 11. That is, the convex portion 19a is fitted into the hole 19b so as to form the positioning portion, which prevents rotation of first wiring member 11. Convex portion 19a may be formed on first wiring member 11, and fitted into hole 19b formed in third wiring member 16.

Accordingly, the rotation of first wiring member 11 by rotational fixing with fixing members 20 etc. is stopped by positioning portion 19a,19b, and the rotational force is not applied to current detection device 10. Then, joint interface between resistor body 13 and wiring members 11,12 is not affected by the rotational force applied by rotational fixing with fixing members 20 etc. Advantage of the invention is same with first embodiment.

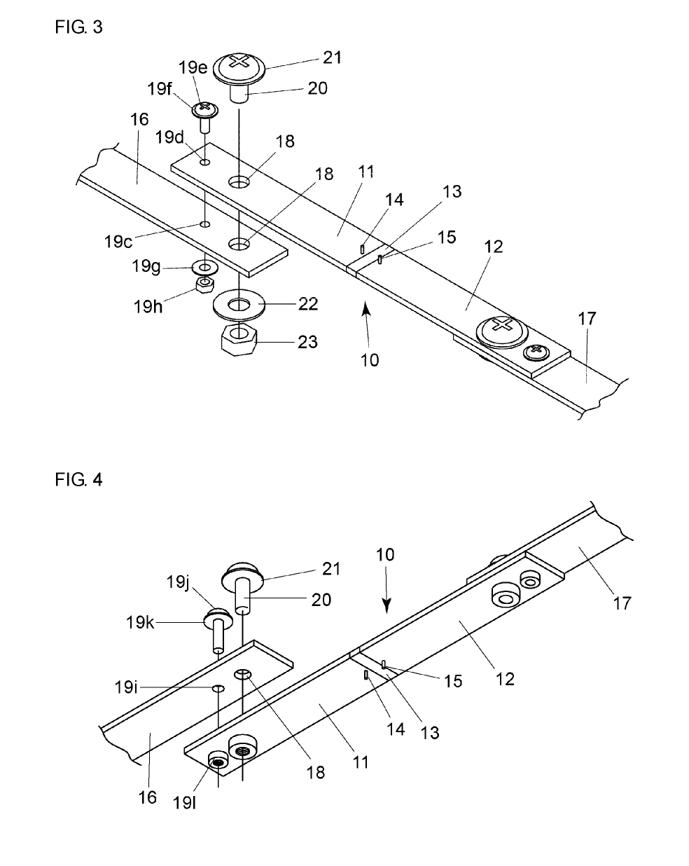

FIG. 3 illustrates a current detection device of third embodiment, in which, positioning portion 19c,19d is formed as a hole 19c in third wiring member 16 and a hole 19d in first wiring member 11. That is, a hole 19c is formed in third wiring member 16, a hole 19d is formed in first wiring member 11, a bolt 19e is inserted into hole 19c, hole 19d, washer 19f, washer 19g, and rotationally fixed by a nut 19h. Thus, positioning portion 19c,19d is formed.

Accordingly, the rotation of first wiring member 11 by rotational fixing with fixing members 20 etc. is stopped by the positioning portion 19c,19d and the rotational force is not applied to current detection device 10. Then, the joint interface between resistor body 13 and wiring members 11,12 is not affected by the rotational force applied by rotational fixing with fixing members 20 etc. Advantage of the invention is same with above embodiments.

FIG. 4 illustrates a current detection device of fourth embodiment, in which, a nut 19l is fixed on third wiring member 16 beforehand. That is, a hole 19i is formed in third wiring member 16, a hole corresponding to hole 19i is formed in first wiring member 11, and nut 19l is fixed to the hole by pressure fitting, electron beam welding, or laser beam welding etc.

Then, a bolt 19j is inserted into these holes, washer 19k, and rotationally fixed into the nut 19l. Further, instead of the nut 19l, screw threads may be formed in these holes in first wiring member 11 and third wiring member 16. However, tightening strength of bolt 19j can be kept high by installing the nut 19l fixed on first wiring member 11.

Accordingly, the rotation of first wiring member 11 by rotational fixing with fixing members 20 etc. is stopped by positioning portion 19i,19j,19k,19l, etc. and the rotational force of rotational fixing is not applied to current detection device 10. Then, joint interface between resistor body 13 and wiring members 11,12 is not affected by the rotational force applied by rotational fixing with fixing members 20 etc. Advantage of the invention is same with above embodiments.

FIG. 5 illustrates a current detection device of fifth embodiment, in which, a positioning portion 19m for stopping a rotation of wiring member 11 is provided as a jig 19m etc. for connecting current detection device 10 to bus bar 16. That is, first wiring member 11 and third wiring member 16 are positioned by positioning portion, that is a jig 19m, and fixed by rotational fixing with fixing members (bolt 20, nut 23, etc.). Thus, the positioning portion 19m may be provided at an outside of the current detection device 10.

Accordingly, rotation of first wiring member 11 by rotational fixing with fixing members 20 etc. is stopped by the positioning portion 19m and the rotational force by rotational fixing with fixing members is not applied to current detection device 10. Then, joint interface between resistor body 13 and wiring members 11,12 is not affected by the rotational force applied by rotational fixing with fixing members 20 etc. Advantage of the invention is same with above embodiments.

FIG. 6 illustrates a current detection device of sixth embodiment, in which, through holes 19n, 19o, 19p are positioning portions. Through holes 18 in current detection device 10 is positioned to a through hole 18 in third wiring member 16 and in fourth wiring member 17. The third wiring member 16 and the fourth wiring member 17 both consist of conductive metal material for configuring a current path. Similarly, through holes 19n and 19o in first wiring member 11 is positioned to through holes 19n and 19o in third wiring member 16. A through hole 19p in second wiring member 12 is positioned to a through hole 19p in fourth wiring member 17.

First wiring member 11 and third wiring member 16 are overlapped at a portion of their surfaces, and second wiring member 12 and fourth wiring member 17 are overlapped at a portion of their surfaces. Positioning bolts are respectively inserted into overlapped through holes 19p, 19n, 19o and rotationally fixed by nuts. Thus, positioning portions are formed, and first wiring member 11 and third wiring member 16, second wiring member 12 and fourth wiring member 17 are respectively positioned.

Bolts 20 are respectively inserted into through holes 18 in first wiring member 11 and third wiring member 16, and into through holes 18 in second wiring member 12 and fourth wiring member 17, and rotationally fixed by nuts 23, which are installed on the opposite mount surface of bolts 20. Accordingly, rotation of first wiring member 11 and second wiring member 12 by rotational fixing with fixing members 20 etc. is stopped by the positioning portions 19p, 19n, 19o and the rotational force by rotational fixing with fixing members is not applied to the current detection device 10. Then, joint interface between resistor body 13 and wiring members 11,12 is not affected by the rotational force applied by rotational fixing with fixing members 20 etc. Advantage of the invention is same with above embodiments.

The embodiment is an example that first wiring member 11 is connected to L-shaped portion of third wiring member 16. According to a plural of positioning portions 19n,19o at L-shaped portion, stronger connection and more accurate positioning becomes possible.

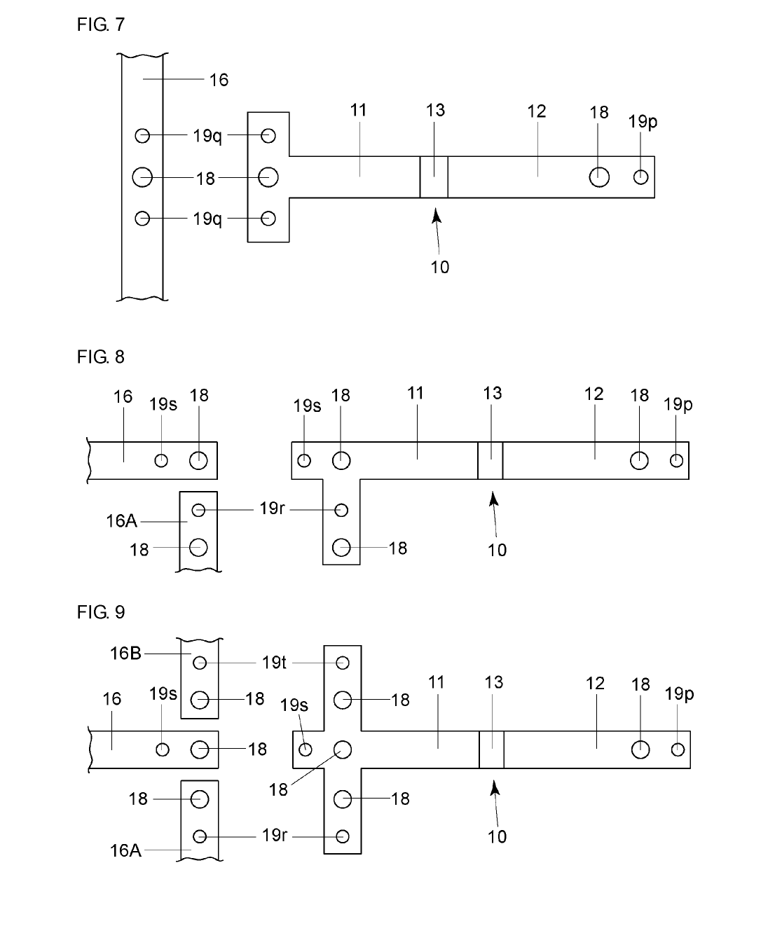

FIG. 7 illustrates a current detection device of seventh embodiment, in which, first wiring member 11 has a T-shaped end. The through hole 18 for rotational fixing and a pair of through holes 19q at both sides of the hole 18 for positioning are formed in T-shaped end of first wiring member 11 and in third wiring member 16. A pair of bolts is inserted into a pair of through holes 19q in first wiring member 11 and in third wiring member 16 and rotationally fixed with nuts so as to form the positioning portions at both sides of through hole 18.

Accordingly, rotation of first wiring member 11 by rotational fixing with fixing members is stopped by the positioning portions 19q, and then rotational force by rotational fixing is not applied to the joint interface between resistor body 13 and first and second wiring members 11,12. Advantage of the invention is same with above embodiments. According to the embodiment, by a plural of positioning portions being provided, stronger connection and more accurate positioning becomes possible.

FIG. 8 illustrates a current detection device of eighth embodiment. According to the embodiment, first wiring member 11 has a function to connect to separated two third wiring members 16,16A and to position to them. That is, through hole 19s in third wiring member 16 is positioned to through hole 19s in first wiring member, and through hole 19r in third wiring member 16A is positioned to through hole 19r in first wiring member 11. And, positioning portions 19s,19r are formed by fixing members, which rotationally fix these members.

First wiring member 11 and third wiring members 16,16A are rotationally fixed by fixing members inserted into two through holes 18. Accordingly, rotation of first wiring member 11 by rotational fixing with fixing members is stopped by the positioning portions 19s, 19r. And then rotational force of rotational fixing is not applied to the joint interface between resistor body 13 and first and second wiring members 11,12. Advantage of the invention is same with above embodiments.

FIG. 9 illustrates a current detection device of ninth embodiment. According to the embodiment, first wiring member 11 has a function to connect to three third wiring members 16, 16A, 16B and to position to them. That is, through hole 19s in third wiring member is positioned to through hole 19s in first wiring member, through hole 19r in third wiring member 16A is positioned to through hole 19r in first wiring member, through hole 19t in third wiring member is positioned to through hole 19t in first wiring member, and these through holes are rotationally fixed by fixing members to form positioning portions 19r,19s,19t.

First wiring member 11 and three third wiring members 16,16A,16B are tightened and fixed by rotationally fixing at three through holes 18 by fixing members. Accordingly, rotation of first wiring member 11 by rotational fixing with fixing members is stopped by the positioning portions 19s,19r,19t. And then the rotational force by rotational fixing is not applied to the joint interface between resistor body 13 and first and second wiring members 11,12. Advantage of the invention is same with above embodiments.

As an embodiment, a current detection device, which has longer wiring members than usual shunt resistor having a bus bar function, has been explained. However, present invention is applicable to usual shunt resistors having short wiring members 11,12 connected to resistor body 13. Although embodiments of the invention have been explained, however the invention is not limited to above embodiments, and various changes and modifications may be made within scope of the technical concept of the invention.

### INDUSTRIAL APPLICABILITY

The invention can be suitably used for current detection devices, which measures a current flowing through a bus bar.

1. A shunt type current detection device comprising:
a first wiring member and a second wiring member those consisting of a conductive metal material;
a resistor body consisting of a metal material having a lower temperature coefficient of resistance than those wiring members and the resistor body joined onto the first wiring member and the second wiring member;
a through hole formed in the first wiring member for inserting a fixing member for rotational fixing; and
a positioning portion for preventing rotation of the first wiring member caused by rotational fixing with fixing members.

2. The current detection device of claim 1, wherein the positioning portion includes a projected part or a through hole formed in the first wiring member.

3. The current detection device of claim 1, wherein the positioning portion is formed at an end portion of the first wiring member opposite to a joint interface with the resistor body.

4. The current detection device of claim 1, wherein a through hole in a third wiring member consisting of conductive metal material for configuring a current path is positioned to the through hole in the first wiring member;
wherein the first wiring member and the third wiring member are overlapped with each other at a portion of their surfaces; and
wherein the first wiring member and the third wiring member are positioned by the positioning portion, and rotationally fixed with fixing members.

5. A method for connecting a current detection device, comprising:
positioning a through hole in a third wiring member consisting of a conductive metal material for configuring a current path, to a through hole in a first wiring member of the current detection device;
the first wiring member and the third wiring member being overlapped with each other at a portion of their surfaces; and
the first wiring member and the third wiring member being positioned by a positioning portion for preventing rotation of the first wiring member caused by rotational fixing with fixing members, and rotationally fixed with fixing members.
